(19) United States
(12) Patent Application Publication
(10) Pub. No.: US 2007/0155067 A1
(43) Pub. Date: Jul. 5, 2007

(54) METHOD OF FABRICATING POLYCRYSTALLINE SILICON FILM AND METHOD OF FABRICATING THIN FILM TRANSISTOR USING THE SAME

(75) Inventors: Kyung-bae Park, Seoul (KR); Takashi Noguchi, Gyeonggi-do (KR); Hyuck Lim, Seoul (KR); Jang-yeon Kwon, Gyeonggi-do (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Gyeonggi-do (KR)

(21) Appl. No.: 11/553,693

(22) Filed: Oct. 27, 2006

(30) Foreign Application Priority Data
Dec. 30, 2005 (KR) 10-2005-0135845

(51) Int. Cl. H01L 21/84; H01L 21/00; H01L 21/20; H01L 21/36

(52) U.S. Cl. 438/149; 438/482; 438/486; 438/488

(57) ABSTRACT

Disclosed herein are methods of fabricating a polycrystalline silicon film and methods of fabricating a thin film transistor (TFT) using the same. The method of fabricating a polycrystalline silicon film includes forming an electrically insulating thermally conductive layer using a material selected from the group consisting of aluminum-containing ceramics, cobalt-containing ceramics, and iron-containing ceramics, on a substrate; forming an amorphous silicon layer on the thermally conductive layer; forming an amorphous silicon island by patterning the amorphous silicon layer; and crystallizing amorphous silicon by annealing the amorphous silicon island. A polycrystalline silicon film having a very large grain size and a TFT using the same can be formed in desired positions.

### CROSS-REFERENCE TO RELATED PATENT APPLICATIONS

This application claims priority to Korean Patent Application No. 10-2005-0135845, filed on Dec. 30, 2005 in the Korean Intellectual Property Office, and all the benefits accruing therefrom under 35 U.S.C. §119(a), the contents of which is incorporated herein by reference in its entirety.

### BACKGROUND OF THE INVENTION

1 . Field of the Invention

The present invention relates to a method of fabricating a polycrystalline silicon (poly-Si) film and a method of fabricating a thin film transistor (TFT) using the same. More particularly, the present invention relates to a method of fabricating silicon having a large grain size by which the position of an element can be determined and a method of fabricating a thin film transistor (TFT) using the same.

2. Description of the Related Art

Recently, research on low temperature poly-Si thin film transistors (LTPS TFT) used in organic light emitting displays, liquid crystal displays (LCDs), and the like has rapidly advanced; and studies on system on glass (SOG) from which an external driver integrated circuit (IC) is completely removed have increased. Since the external driver IC in the SOG are formed together on a display panel, a line for connecting the panel and the external driver IC is not needed. Thus, defects of a display can be reduced and the reliability thereof can be greatly improved. The ultimate objective will be a SOG in which all display systems, including a controller as well as data and gate driver ICs, are integrated on the panel. To achieve this objective, the mobility of the LTPS should be larger than 400 square centimeters per Volt second (cm²/Vsec), and the uniformity thereof should be excellent. However, conventional methods, such as excimer laser annealing (ELA), sequential lateral solidification (SLS), and metal-induced lateral crystallization (MILC), are not yet conducive to the manufacture of LTPS having this desired properties.

Methods of fabricating polycrystalline silicon include a method of directly depositing polycrystalline silicon and a method of crystallizing amorphous silicon after depositing the amorphous silicon. As polycrystalline silicon obtained by crystallization has a larger grain size, it exhibits a higher field effect mobility. On the other hand, a uniform degree of the grains (i.e., the uniformity) is lowered. Conventional ELA methods are limited in the amount that the grain size of polycrystalline silicon can be increased.

A method of fabricating polycrystalline silicon having a grain size of several micrometers (μm) has recently been developed. This new crystallization method has been conducive to the manufacture of lateral grains having a length of 4.6 μm. This method requires a capping layer for an oxide formed on and under amorphous silicon, and an air gap so as to control the crystallization rate of the amorphous silicon. Thus the method requires additional steps, in particular, additional steps of forming and removing a sacrificial layer so as to obtain the air gap. The capping layer has to be removed in the last step. These additional steps are not desirable for mass production, and, in particular, may adversely affect yield and may further increase manufacturing costs.

### BRIEF SUMMARY OF THE INVENTION

The present invention provides a method of fabricating a polycrystalline silicon film having a large grain size by which the position of an element can be controlled, and a method of fabricating a thin film transistor (TFT) using the same.

The present invention also provides a method of fabricating a polycrystalline silicon film by which the manufacturing process is simplified and costs can be reduced, and a method of fabricating a thin film transistor (TFT) using the same.

According to an exemplary embodiment of the present invention, there is provided a method of fabricating a polycrystalline silicon film, which includes forming an electrically insulating, thermally conductive layer using a material selected from the group consisting of aluminum-containing ceramics, cobalt-containing ceramics, and iron-containing ceramics, on a substrate; forming an amorphous silicon layer on the thermally conductive layer; forming an amorphous silicon island by patterning the amorphous silicon layer; and crystallizing amorphous silicon by annealing the amorphous silicon island.

According to another exemplary embodiment of the present invention, there is provided a method of fabricating a thin film transistor (TFT), wherein the TFT includes a channel region, a polycrystalline silicon active layer having a source and drain at both ends of the channel region, a gate disposed to correspond to the channel, and a gate insulating layer disposed between the channel region and the gate. The method includes forming an electrically insulating thermally conductive layer on a substrate; forming an amorphous silicon layer on the thermally conductive layer; forming an amorphous silicon island having a shape corresponding to the active layer by patterning the amorphous silicon layer; and forming the active layer by annealing the amorphous silicon island.

The substrate may be a glass or polymeric substrate. The thermally conductive layer may comprise a material selected from the group consisting of aluminum-containing ceramics (e.g., Al₂O₃ and AlN), cobalt-containing ceramics (e.g., CoO and Co₃N₄), and iron-containing ceramics (e.g., FeO, Fe₂O₃, Fe₃O₄, and Fe₂N).

The TFT can be a bottom gate TFT in which the gate is located under the silicon active layer, or a top gate TFT in which the gate is located on the silicon active layer. Accordingly, the gate of the TFT is formed before the thermally conductive layer.

### BRIEF DESCRIPTION OF THE DRAWINGS

The above and other features and advantages of the present invention will become more apparent from the following detailed description taken in conjunction with the attached drawings, in which:

FIG. 1 schematically illustrates the heat distribution within a thermally conductive layer when a silicon (Si) island is crystallized, as well as a crystallization process based on the heat distribution, according to an exemplary embodiment of a method of fabricating a polycrystalline silicon film of the present invention;

FIG. 2 schematically illustrates a path of heat flow from a Si island, as well as crystallite nucleus generation and growth based on the path of heat flow according to an exemplary embodiment of the present invention;

FIG. 3 is a scanning electron microscope (SEM) image of a polycrystaine silicon film fabricated according to an exemplary embodiment of the present invention;

FIG. 4 is a SEM image of a polycrystalline silicon film fabricated using a conventional method of the prior art;

FIGS. 5A through 5F schematically illustrate an exemplary embodiment of a method of fabricating a polycrystalline silicon film according to the present invention;

FIGS. 6A and 6B are schematic cross-sectional views of a top gate thin film transistor (TFT) and a bottom gate TFT, respectively, fabricated according to an exemplary embodiment of the present invention; and

FIG. 7 is a flowchart illustrating an exemplary embodiment of a method of fabricating a polycrystalline silicon TFT according to the present invention.

### DETAILED DESCRIPTION OF THE INVENTION

The present invention will now be described more fully hereinafter with reference to the accompanying drawings, in which exemplary embodiments of the present invention are shown. This invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, and the like may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In exemplary embodiments of a process of fabricating a polycrystalline silicon (Si) film of the present invention, a silicon (Si) island is formed on a material having a high thermal conductivity (e.g., an AlN thermally conductive layer). The thermally conductive layer is formed on a quartz, glass or polymeric (e.g., plastic) substrate.

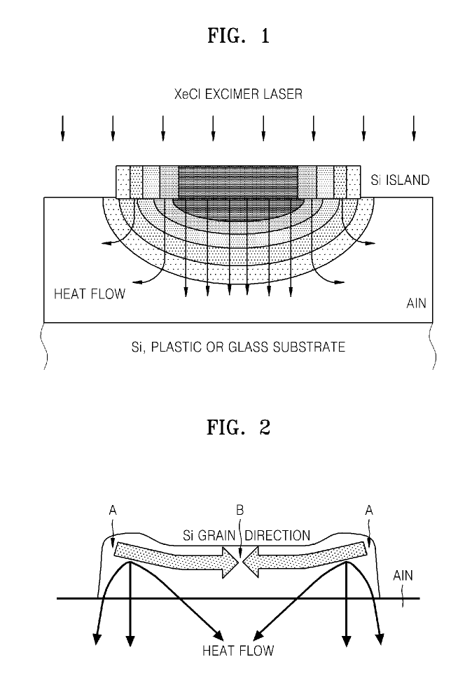

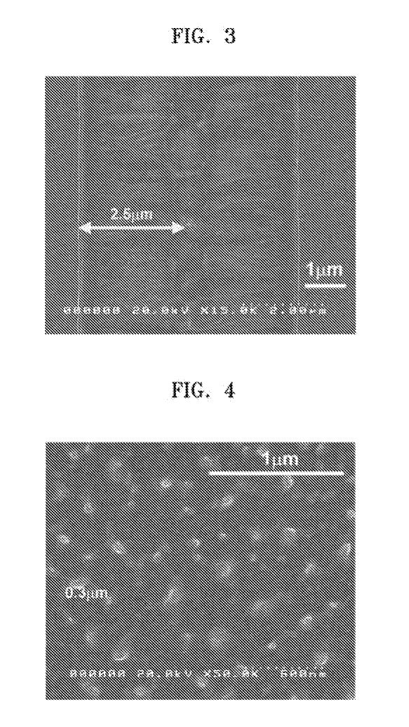

Light, such as from an XeCl excimer laser having a wavelength of about 308 nanometers (nm), is irradiated onto the Si island such that the Si island is sufficiently heated and preferably completely melts. The heated Si island immediately conducts heat. At this time, a three-dimensional heat flow is generated within the thermally conductive layer disposed below the Si island. The irradiation of light and the consequent heat distribution within the thermally conductive layer is shown in FIG. 1. Further, FIG. 2 schematically illustrates a path of heat flow from the Si island and the crystallite nucleus generation and growth based on the path of heat flow. Thermal conduction in the thermally conductive layer occurs faster and to a greater extent in a latitudinal direction of the thermally conductive layer than in the substrate disposed below the thermally conductive layer. In the drawings, arrows represent the path of heat flow for this thermal conduction. The relatively darker portions of the drawings represent higher temperatures, and the relatively brighter portions of the drawings represent lower temperatures. The central portion of the Si island has a higher temperature than other portions (i.e., the temperature of the Si island is lower at the sides or outer portions). Due to this lateral thermal gradient, a thermal conducting path is formed and crystal growth caused thereby occurs as illustrated in FIG. 2. That is, because of the fast thermal conduction caused by the thermally conductive layer, heat is dissipated faster from the edges of the Si island. Thus, a crystallite nucleus is first formed at both ends (A) of the Si island, and growth is gradually performed in a middle portion of the Si island. Finally, a grain boundary (B) is generated in the center of the Si island.

According to the present invention, since the Si island is pre-patterned, cooling occurs more rapidly from both edges of the Si island during annealing and the crystallite nucleus is generated here. That is, since the generation position of the crystallite nucleus is determined, the Si island can be thermally heated to a fully melted condition. The possibility of full melting allows a very wide process window, that is, thermal treatment in a very wide temperature range. Since the position and size of the pre-patterned Si island can be controlled by design, polycrystalline silicon of good quality can be formed in a desired position on the substrate.

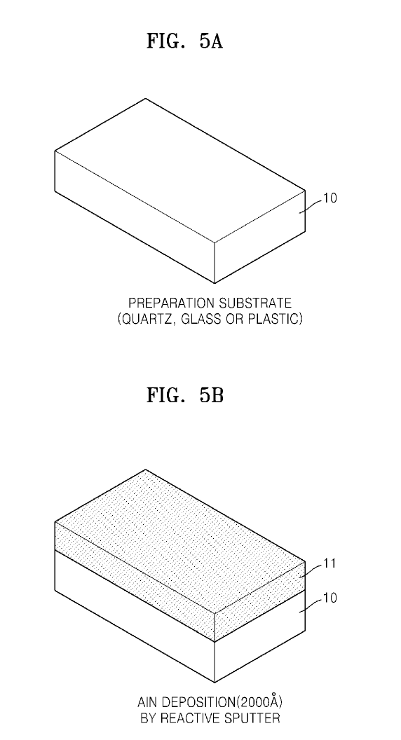

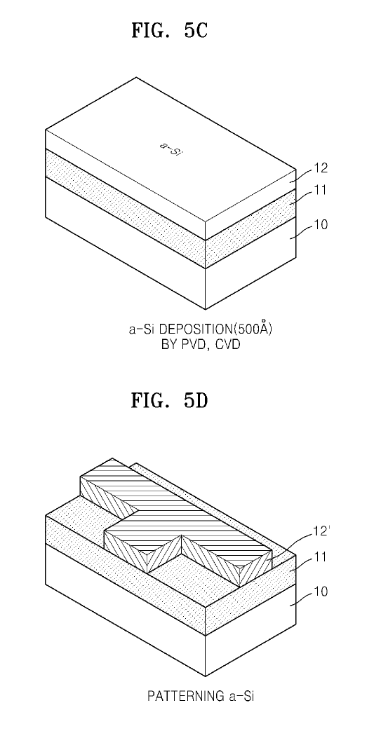

According to the present invention, polycrystalline silicon as shown in FIG. 3 can be obtained. FIG. 3 is a scanning electron microscope (SEM) image of a polycrystalline silicon film fabricated according to the present invention. Referring to FIG. 3, crystallites having average widths of about 2.5 micrometers (μm) can be seen along with grain boundaries in a middle portion of the polycrystalline silicon. In contrast, FIG. 4 is a SEM image of polycrystalline silicon fabricated using a conventional method of the prior art. The grain size of the polycrystalline silicon obtained using the conventional method is only about 0.3 μm, which is significantly smaller than that of the polycrystalline silicon obtained using a method of the present invention.

The above-described thermally conductive layer has a higher thermal conductivity compared to the underlying substrate and the silicon. An exemplary material, which can be used as the thermally conductive layer is AlN. Since AlN has a thermal conductivity greater than 260 Watts per degree milliKelvin (W/mK) and has a band gap of about 6.3 electron-Volts (eV), it is a good electrical insulator. In addition, AlN has a high physical strength, a high optical transparency, and good chemical stability. It is for these reasons that AlN is an exemplary material used for manufacturing a polycrystalline silicon film according to the present invention. Other exemplary materials that can be used for the thermally conductive layer include aluminum-containing ceramics (e.g., Al₂O₃, AlN, and the like), cobalt-containing ceramics (e.g., CoO, Co₃N₄, and the like), and iron-containing ceramics (e.g., FeO, Fe₂O₃, Fe₃O₄, Fe₂N, and the like), which are highly thermally conductive materials.

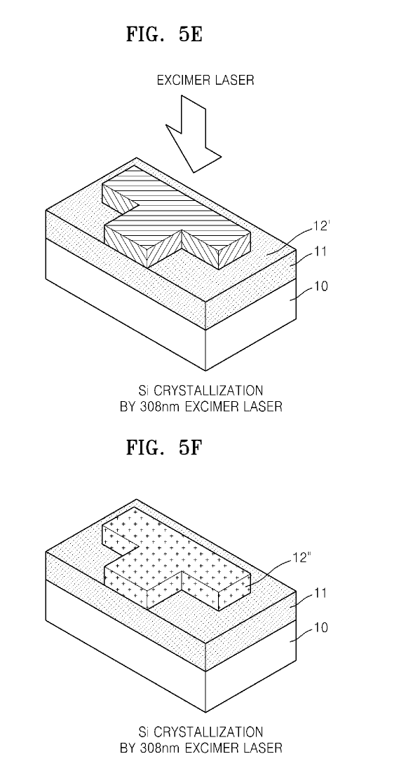

An exemplary embodiment of a method of fabricating a polycrystalline silicon film according to the present invention will now be described with reference to FIGS. 5A through 5F. Referring to FIG. 5A, a quartz, glass or polymeric (e.g. plastic) substrate 10 is prepared. As shown in FIG. 5B, a thermally conductive layer 11 is formed of a highly thermally conductive material on the substrate 10 to a thickness of about 2000 Angstroms (Å). In one embodiment, a reactive sputter is used for material deposition. The sputtering target material is Al, and nitrogen flowing at a rate of 10 standard cubic centimeters per minute (sccm) is used as a reaction gas. The pressure inside a the reaction chamber is about 10 milliTorr (mTorr), and the plasma power is about 300 Watts (W).

Referring to FIG. 5, a layer of amorphous silicon (a-Si) 12 is formed on the thermally conductive layer 11 to a thickness of about 500 Å. Chemical vapor deposition (CVD) or physical vapor deposition (PVD) can be used to deposit the a-Si. Si is used as a sputtering target in reactive sputtering PVD. In this case, Ar flowing at a rate of 50 sccm is used as the reaction gas and the pressure is set to about 5 mTorr.

Referring to FIG. 5D, the a-Si 12 is patterned using dry etching, thereby obtaining an Si island 12′. The a-Si island is used as a semiconductor device, for example, as an active layer of a TFT. Here, the island of FIG. 5D has a symbolic shape, but may be formed in various shapes as desired for the particular application.

Referring to FIG. 5E, the a-Si island 12′ is annealed using an excimer laser. In this case, a XeCl excimer laser having a wavelength of about 308 nm is used as the excimer laser. The laser energy is set to be greater than about 400 milliJoules per square centimeter (mJ/cm²). Due to this thermal treatment, a polycrystalline silicon film 12″ having a large grain size is formed on a desired position of the substrate 10, as shown in FIG. 5F.

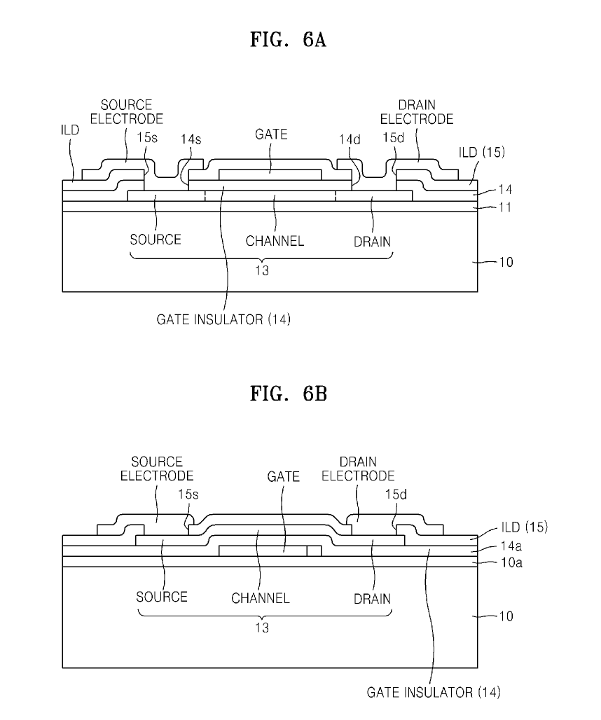

FIGS. 6A and 6B illustrate exemplary embodiments of TFTs fabricated according to the present invention. FIG. 6A illustrates an exemplary embodiment of a top gate TFT in which the gate is located on the silicon active layer, and FIG. 6B illustrates an exemplary embodiment of a bottom gate TFT in which the gate is located under the silicon active layer.

Referring to FIG. 6A, the thermally conducting layer 11, which may be AlN, is formed on a top surface of the substrate 10. The thermally conductive layer 11 functions as a buffer layer. An active layer 13 formed of a polycrystalline silicon film fabricated according to the present invention is disposed on the thermally conductive layer 11. The active layer 13 is divided into a doped source and drain, as well as a channel therebetween. A gate insulating layer 14 is formed on the active layer 13, and through-holes 14s and 14d corresponding to the source and drain, respectively, are formed in the gate insulating layer 14.

A gate is formed on the channel of the active layer 13, and an interlayer dielectric (ILD) 15 is formed on the gate. Through holes 15s and 15d that correspond to the source and drain, respectively, of the active layer 13 and communicate with the through holes 14s and 14d of the gate insulating layer 14 are formed in the ILD 15. A source electrode and a drain electrode are provided on the ILD 15. The source electrode and the drain electrode contact the source and drain, respectively, of the active layer 13 through the through holes 14s and 15s and 14d and 15d.

Referring to FIG. 6B, a buffer layer 10a is formed on a top surface of the substrate 10, and a gate formed of Al or the like, is formed on the buffer layer 10a. A gate insulating layer 14a is formed on the gate. The gate insulating layer 14a is formed of a highly thermally conductive material such as AlN or the like, as described above, and controls the crystallization of the active layer 13 when the active layer 13 is annealed. The active layer 13, which is formed of a polycrystalline silicon film fabricated according to a method of the present invention, is disposed on the gate insulating layer 14a. The active layer 13 is also divided into a doped source and drain, along with a channel therebetween. An ILD 15 is formed on the active layer 13. Through holes 15s and 15d that correspond to the source and drain, respectively, of the active layer 13 are formed in the ILD 15. The source electrode and the drain electrode are provided on the ILD 15. The source electrode and the drain electrode contact the source and drain, respectively, of the active layer 13 through the through holes 15s and 15d, respectively.

For explanatory conveniences, a general method of fabricating a top gate TFT and a bottom gate TFT will now be simply described. The method of fabricating a top gate TFT that will be described below is understood so that a general bottom gate TFT can be easily fabricated, and the method of fabricating a TFT is not limited to the technical scope of the present invention.

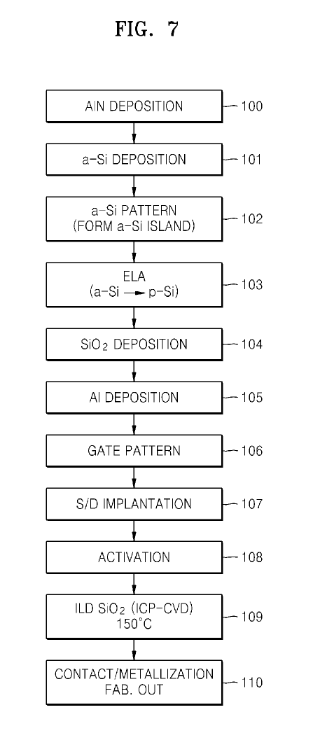

FIG. 7 is a flowchart illustrating an exemplary embodiment of method of fabricating a polycrystalline silicon TFT according to the present invention. First, a highly thermally conductive material is deposited on the substrate 10, shown in the figure as operation 100. The highly thermally conductive material has higher thermal conductivity than the substrate 10 and silicon. As described above, the highly thermally conductive material can be a material selected from the group consisting of aluminum-containing ceramics, cobalt-containing ceramics, and iron-containing ceramics. In an exemplary embodiment, the highly thermally conductive material is AlN. The thickness of the highly thermally conductive material is about 2000 Å and reactive sputtering is used for deposition. The target material is Al, and nitrogen flowing at a rate of about 10 sccm is used as the reaction gas. The pressure inside the reaction chamber is about 10 mTorr and the plasma power is about 300 W.

Subsequently, shown as operation 101 in the figure, amorphous silicon (a-Si) is formed on the highly thermally conductive layer using CVD or reactive sputtering PVD. The thickness of the a-Si is about 500 Å. When reactive sputtering is used for deposition, Si is the sputtering target. In this case, Ar flowing at a rate of about 50 sccm is used as the reaction gas, and the pressure is set to about 5 mTorr.

The a-Si is patterned using dry or wet etching to form a Si island (an active layer) of the TFT (operation 102). Next, the Si island is annealed (operation 103) using an excimer laser annealing (ELA) step so that the a-Si is converted into polycrystalline silicon. In an exemplary embodiment, an XeCl excimer laser having an wavelength of about 308 nm is used, and the laser energy is set to be greater than about 400 mJ/cm². A silicon oxide layer is then deposited (operation 104) using a gate insulating layer on the entire substrate including the polycrystalline Si island (also referred to as the active layer) using plasma enhanced CVD (PE-CVD), inductively coupled plasma enhanced CVD (ICP-CVD), or the like.

A metal, to be processed as a gate, such as an Al layer is deposited on the gate insulating layer (operation 105). The Al layer and the gate insulating layer under the Al layer are patterned so that a gate having a desired shape and the gate insulating layer under the gate are obtained (operation 106). Impurities are injected into both sides of the active layer that is not covered by the gate and the gate insulating layer using an ion shower so that source and drain are formed (operation 107). The source and the drain are activated by a thermal treatment using an XeCl excimer laser having a wavelength of about 308 nm (operation 108). A SiO₂ insulating layer which is an ILD is formed to a thickness of about 3000 nm on the entire substrate including the gate using ICP-CVD, PE-CVD, sputtering, or the like (operation 109). Finally, a contact hole through which the source and the drain communicate is formed on the ILD and a source electrode and a drain electrode are formed by metallization so that a desired TFT is obtained (operation 110).

According to the present invention as described above, a polycrystalline silicon film having a very large grain size and a TFT using the same can be obtained using a simpler process compared to the prior art without requiring additional process steps. In particular, a Si island is pre-formed and crystallized. Thus, polycrystalline silicon can be obtained in a desired position on the substrate.

The method of fabricating a polycrystalline silicon film and the method of fabricating a TFT using the same according to the present invention are suitable for the manufacture of active-matrix liquid crystal displays (AMLCDs), active-matrix organic light emitting diodes (AMOLEDs), solar cells, semiconductor memory devices, and the like. In particular, these methods are very suitable for the manufacture of a TFT that requires high mobility and response and in which a glass or polymeric (e.g., plastic) substrate is used. The methods may also be used to manufacture electronic apparatuses using a TFT as a switching element or an amplification element.

While the present invention has been particularly shown and described with reference to exemplary embodiments, it will be understood by those of ordinary skill in the art that various changes in form and details may be made therein without departing from the spirit and scope of the present invention as defined by the following claims.

What is claimed is:

1. A method of fabricating a polycrystalline silicon film, the method comprising:
forming an electrically insulating thermally conductive layer using a material selected from the group consisting of aluminum-containing ceramics, cobalt-containing ceramics, and iron-containing ceramics, on a substrate,
forming an amorphous silicon layer on the electrically insulating thermally conductive layer;
forming an amorphous silicon island by patterning the amorphous silicon layer; and
crystallizing the amorphous silicon by annealing the amorphous silicon island.

2. The method of claim 1, wherein the aluminum-containing ceramics comprise Al₂O₃ or AlN.

3. The method of claim 1, wherein the cobalt-containing ceramics comprise CoO or Co₃N₄.

4. The method of claim 1, wherein the iron-containing ceramics comprise FeO, Fe₂O₃, Fe₃O₄, or Fe₂N.

5. The method of claim 1, wherein annealing the amorphous silicon island comprises excimer laser annealing the amorphous silicon island.

6. The method of claim 2, wherein annealing the amorphous silicon island comprises excimer laser annealing the amorphous silicon island.

7. The method of claim 3, wherein annealing the amorphous silicon island comprises excimer laser annealing the amorphous silicon island.

8. The method of claim 4, wherein annealing the amorphous silicon island comprises excimer laser annealing the amorphous silicon island.

9. The method of claim 5, wherein an energy density during the annealing of the amorphous silicon island is greater than about 400 milliJoules per centimeter squared.

10. A method of fabricating a thin film transistor, wherein the thin film transistor includes a channel region, a polycrystalline silicon active layer having a source and drain at the ends of the channel region, a gate disposed to correspond to the channel, and a gate insulating layer disposed between the channel region and the gate, the method comprising:
forming an electrically insulating thermally conductive layer on a substrate;
forming an amorphous silicon layer on the thermally conductive layer;
forming an amorphous silicon island having a shape corresponding to the active layer by patterning the amorphous silicon layer; and
forming the active layer by annealing the amorphous silicon island.

11. The method of claim 10, wherein the thermally conductive layer is formed of a material selected from the group consisting of aluminum-containing ceramics, cobalt-containing ceramics, and iron-containing ceramics.

12. The method of claim 11, wherein the aluminum-containing ceramics comprise Al₂O₃ or AlN.

13. The method of claim 11, wherein the cobalt-containing ceramics comprise CoO or Co₃N₄.

14. The method of claim 11, wherein the iron-containing ceramics comprise FeO, Fe₂O₃, Fe₃O₄, or Fe₂N.

15. The method of claim 10, wherein annealing the amorphous silicon island comprises excimer laser annealing the amorphous silicon island.

16. The method of claim 11, wherein annealing the amorphous silicon island comprises excimer laser annealing (ELA) the amorphous silicon island.

17. The method of claim 12, wherein annealing the amorphous silicon island comprises excimer laser annealing (ELA) the amorphous silicon island.

18. The method of claim 13, wherein annealing the amorphous silicon island comprises excimer laser annealing (ELA) the amorphous silicon island.

19. The method of claim 14, wherein annealing the amorphous silicon island comprises excimer laser annealing (ELA) the amorphous silicon island.

20. The method of claim 15, wherein an energy density during the annealing of the amorphous silicon island is greater than about 400 milliJoules per centimeter squared.
